(19) United States
(12) Patent Application Publication
(10) Pub. No.: US 2026/0114203 A1
(43) Pub. Date: Apr. 23, 2026

(54) CUTTING METHOD FOR WORKPIECE

(71) Applicant: DISCO CORPORATION, Tokyo (JP)

(72) Inventors: Kokichi MINATO, Tokyo (JP); Norifumi HODOHARA, Tokyo (JP)

(21) Appl. No.: 19/325,595

(22) Filed: Sep. 11, 2025

(30) Foreign Application Priority Data
Oct. 18, 2024 (JP) 2024-184221

(51) Int. Cl. H01L 21/304

(52) U.S. Cl. CPC H10P 52/00

(57) ABSTRACT

The cutting method for a workpiece includes cutting an outer circumferential portion of one surface of the workpiece to form an annular step portion by causing a cutting blade to cut into a chamfered portion of the one surface of the workpiece held by a holding surface of a chuck table and rotating the chuck table. The cutting method also includes cutting a bottom portion of the annular step portion by relatively moving the chuck table and the cutting blade after the cutting the outer circumferential portion to form the annular step portion. The cutting the bottom portion of the annular step portion includes relatively moving the chuck table and the cutting blade along a longitudinal direction of a spindle on which the cutting blade is mounted in a state in which the height position of the spindle relative to the chuck table is kept.

### BACKGROUND OF THE INVENTION

### FIELD OF THE INVENTION

The present invention relates to a cutting method for a workpiece by which a chamfered portion in one surface of the workpiece having the chamfered portion at an outer circumferential portion of this one surface is removed and an annular step portion is formed at the outer circumferential portion of this workpiece.

### Description of the Related Art

In manufacturing of a semiconductor device chip, for example, a wafer (that is, workpiece) is divided into a plurality of semiconductor device chips by splitting the wafer along a plurality of planned dividing lines set in a lattice manner in a front surface of the wafer. Before the wafer is divided in this manner, a device such as an integrated circuit (IC) is formed in each of regions marked out by the plurality of planned dividing lines, and subsequently a back surface of the wafer is ground to thin the wafer to a predetermined thickness. Thereafter, the wafer is divided.

Incidentally, in a case in which chamfered portions are formed at outer circumferential portions of the front surface and the back surface of a wafer, if the back surface of the wafer is ground to thin a thickness of the wafer to half or less of the thickness before the grinding, a generally-called sharp edge (referred to also as knife edge) is formed at an outer circumferential edge of the front surface of the wafer. The sharp edge possibly induces breakage of the wafer.

There is known a technique in which the following process is executed in order to prevent the breakage of a wafer attributed to the sharp edge (for example, refer to Japanese Patent Laid-open No. 2000-173961). Before grinding of the back surface, an outer circumferential portion of the front surface of the wafer is cut by a cutting blade to thereby remove a chamfered portion of the front surface (that is, execute generally-called edge trimming). Thereafter, the back surface of the wafer is ground.

An annular step portion is formed at the outer circumferential portion of the front surface of the wafer by the edge trimming. In general, a cutting mark is formed in a bottom portion of this step portion due to the cutting by the cutting blade. The cutting mark formed in the bottom portion of the step portion includes periodic roughness in a radial direction of the wafer.

If the cutting mark including such roughness exists in the bottom portion of the step portion, for example, when a distance from a measuring instrument to the bottom portion of the step portion is measured by an optical method to calculate a distance from the bottom portion of the step portion to the back surface of the wafer (that is, remaining thickness of the outer circumferential portion of the wafer), measurement light is sometimes not properly reflected by the bottom portion of the step portion. In this case, a problem that an excessive measurement error is obtained, that the measurement itself is impossible, or the like occurs.

### SUMMARY OF THE INVENTION

The present invention has been made in view of such a problem, and intends to reduce roughness in a bottom portion of an annular step portion formed at an outer circumferential portion of a workpiece by edge trimming.

In accordance with an aspect of the present invention, there is provided a cutting method for a workpiece by which a chamfered portion in one surface of the workpiece having the chamfered portion at an outer circumferential portion of the one surface is removed and an annular step portion is formed at the outer circumferential portion of the one surface. The cutting method includes cutting the outer circumferential portion of the one surface of the workpiece to form the step portion by causing a cutting blade mounted on a tip portion of a spindle with a longitudinal direction disposed along a holding surface of a chuck table to cut into the chamfered portion of the one surface of the workpiece held by the holding surface and rotating the chuck table. The cutting method includes also cutting a bottom portion of the step portion by relatively moving the chuck table and the cutting blade after the cutting the outer circumferential portion to form the step portion. The cutting the bottom portion of the step portion includes relatively moving the chuck table and the cutting blade along the longitudinal direction of the spindle in a state in which the height position of the spindle relative to the chuck table is kept.

Preferably, in the cutting the bottom portion of the step portion, the chuck table and the cutting blade are relatively moved while the chuck table is rotated.

Further, preferably, the cutting method for a workpiece further includes moving the cutting blade relative to the chuck table such that the movement direction of the cutting blade relative to the chuck table is the opposite direction to the movement direction of the cutting blade relative to the chuck table in the cutting the bottom portion of the step portion in the state in which the height position of the spindle relative to the chuck table is kept, and the cutting the bottom portion of the step portion and the moving the cutting blade relative to the chuck table are repeated a plurality of times.

Moreover, preferably, the cutting method for a workpiece further includes rotating the chuck table by a predetermined angle after the cutting the bottom portion of the step portion, and after the rotating the chuck table by the predetermined angle, moving the cutting blade relative to the chuck table such that the movement direction of the cutting blade relative to the chuck table is the opposite direction to the movement direction of the cutting blade relative to the chuck table in the cutting the bottom portion of the step portion in the state in which the height position of the spindle relative to the chuck table is kept.

Further, preferably, the cutting the bottom portion of the step portion, the rotating the chuck table by the predetermined angle after the cutting the bottom portion of the step portion, and the moving the cutting blade relative to the chuck table after the rotating the chuck table by the predetermined angle are repeated in that order.

Moreover, preferably, the workpiece has a lower wafer and an upper wafer that has chamfered portions at outer circumferential portions of both surfaces and is overlapped with and fixed to the lower wafer. The step portion is formed at the outer circumferential portion of the upper wafer in the cutting the outer circumferential portion to form the step portion, and a bottom portion of the step portion of the upper wafer is cut in the cutting the bottom portion of the step portion.

Further, preferably, the cutting method for a workpiece further includes irradiating the bottom portion of the step portion for which the cutting the bottom portion of the step portion has been executed with measurement light from a sensor head and measuring a distance from the other surface of the workpiece located on the opposite side to the one surface to the bottom portion of the step portion.

Moreover, preferably, the cutting method for a workpiece further includes, after the cutting the bottom portion of the step portion, making the step portion deeper and forming the step portion with an outer circumferential side surface of the upper wafer, an outer circumferential side surface of the lower wafer, and an outer circumferential portion of the lower wafer by causing the cutting blade to cut into the bottom portion of the step portion and rotating the chuck table, and cutting the outer circumferential portion of the lower wafer forming the step portion after the making the step portion deeper.

Further, preferably, the cutting method for a workpiece further includes imaging the bottom portion of the step portion for which the cutting the outer circumferential portion of the lower wafer has been executed.

In the cutting method for a workpiece according to the aspect of the present invention, the annular step portion is formed at the outer circumferential portion of the one surface of the workpiece in the cutting the outer circumferential portion to form the step portion, and subsequently the bottom portion of the step portion is cut in the cutting the bottom portion of the step portion. In particular, the cutting the bottom portion of the step portion can reduce roughness formed in the bottom portion of the step portion because moving the cutting blade along the longitudinal direction of the spindle in the state in which the height position of the spindle relative to the chuck table is kept is included.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a flowchart of a cutting method;

FIG. 2A is a side view of a wafer;

FIG. 2B is a top view of the wafer;

FIG. 3A is a partially sectional side view depicting a first cutting step;

FIG. 3B is a top view depicting the first cutting step;

FIG. 4A is a partially sectional side view depicting the time of start of a second cutting step;

FIG. 4B is a top view depicting the time of the start of the second cutting step;

FIG. 5A is a partially sectional side view depicting the time of end of the second cutting step;

FIG. 5B is a top view depicting the time of the end of the second cutting step;

FIG. 6A is a schematic top view of the wafer after the second cutting step;

FIG. 6B is a schematic sectional view along line A-A in FIG. 6A;

FIG. 6C is a schematic sectional view along line B-B in FIG. 6A;

FIG. 7 is a partially sectional side view depicting a measurement step;

FIG. 8A is a partially sectional side view depicting the time of start of the second cutting step according to a second embodiment;

FIG. 8B is a top view depicting the time of the start of the second cutting step according to the second embodiment;

FIG. 9A is a top view depicting a first example of the wafer after the second cutting step according to the second embodiment;

FIG. 9B is a top view depicting a second example of the wafer after the second cutting step according to the second embodiment;

FIG. 10 is a flowchart of a cutting method according to a third embodiment;

FIG. 11A is a top view depicting a first example of the wafer cut by the cutting method of the third embodiment;

FIG. 11B is a top view depicting a second example of the wafer cut by the cutting method of the third embodiment;

FIG. 12 is a flowchart of a cutting method according to a fourth embodiment;

FIG. 13A is a top view depicting a first example of the wafer cut by the cutting method of the fourth embodiment;

FIG. 13B is a top view depicting a second example of the wafer cut by the cutting method of the fourth embodiment;

FIG. 14 is a flowchart of a cutting method according to a fifth embodiment;

FIG. 15A is a side view of a bonded wafer;

FIG. 15B is a top view of the bonded wafer;

FIG. 16A is a partially sectional side view depicting the first cutting step;

FIG. 16B is a partially sectional side view depicting the second cutting step;

FIG. 17 is a partially sectional side view depicting the measurement step;

FIG. 18A is a partially sectional side view depicting an additional first cutting step;

FIG. 18B is a partially sectional side view depicting an additional second cutting step;

FIG. 19A is a partially sectional side view depicting an imaging step;

FIG. 19B is a schematic diagram of an image obtained in the imaging step of the fifth embodiment; and

FIG. 19C is a schematic diagram of an image obtained in an existing imaging step.

### DETAILED DESCRIPTION OF THE PREFERRED EMBODIMENTS

### First Embodiment

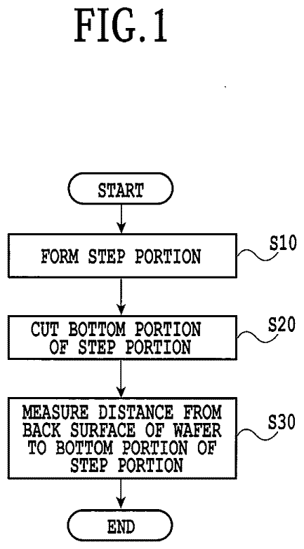

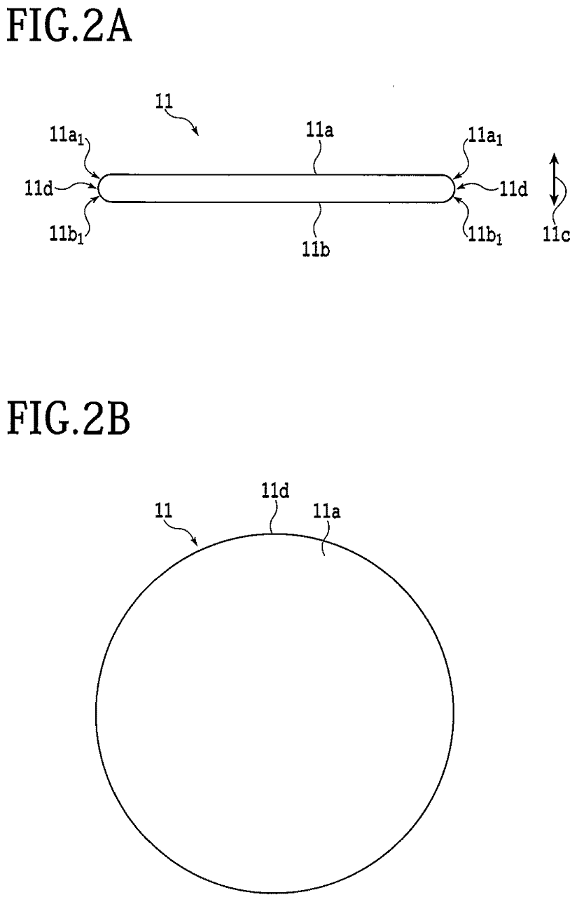

An embodiment according to an aspect of the present invention is described with reference to the accompanying drawings. FIG. 1 is a flowchart of a cutting method for a wafer 11 (see FIGS. 2A and 2B). In a first embodiment, the respective steps are executed in order of a first cutting step S10, a second cutting step S20, and a measurement step S30.

First, the wafer (workpiece) 11 with a circular disc shape is described with reference to FIGS. 2A and 2B. FIG. 2A is a side view of the wafer 11. FIG. 2B is a top view of the wafer 11.

The wafer 11 has a front surface (that is, one surface) 11a and a back surface (that is, the other surface) 11b. The front surface 11a and the back surface 11b are located on the opposite sides in a thickness direction 11c of the wafer 11. The wafer 11 has, for example, a diameter of approximately 300 mm (that is, 12 inches) and a thickness of approximately 775 μm.

A plurality of planned dividing lines (not depicted) are set in a lattice manner in the front surface 11a of the wafer 11. A device (not depicted) such as an IC is formed in each of rectangular regions marked out by the plurality of planned dividing lines.

The front surface 11a has a chamfered portion 11a₁ at an outer circumferential portion. Similarly, the back surface 11b also has a chamfered portion 11b₁ at an outer circumferential portion. The chamfered portions 11a₁ and 11b₁ are each referred to also as bevel portion.

In the thickness direction 11c of the wafer 11, an edge 11d that defines the outermost circumference of the wafer 11 in top view exists between the chamfered portion 11a₁ of the front surface 11a and the chamfered portion 11b₁ of the back surface 11b.

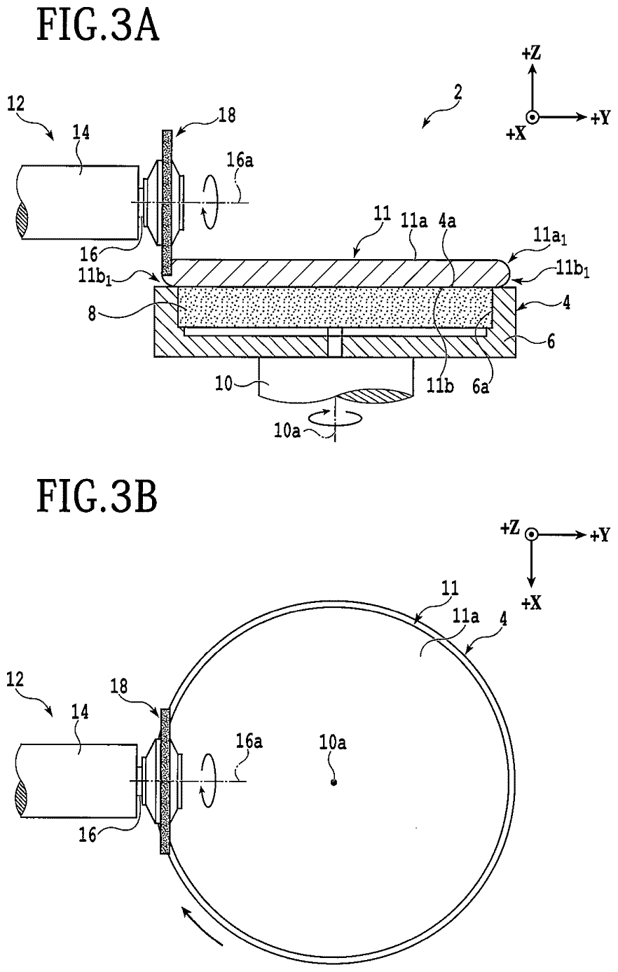

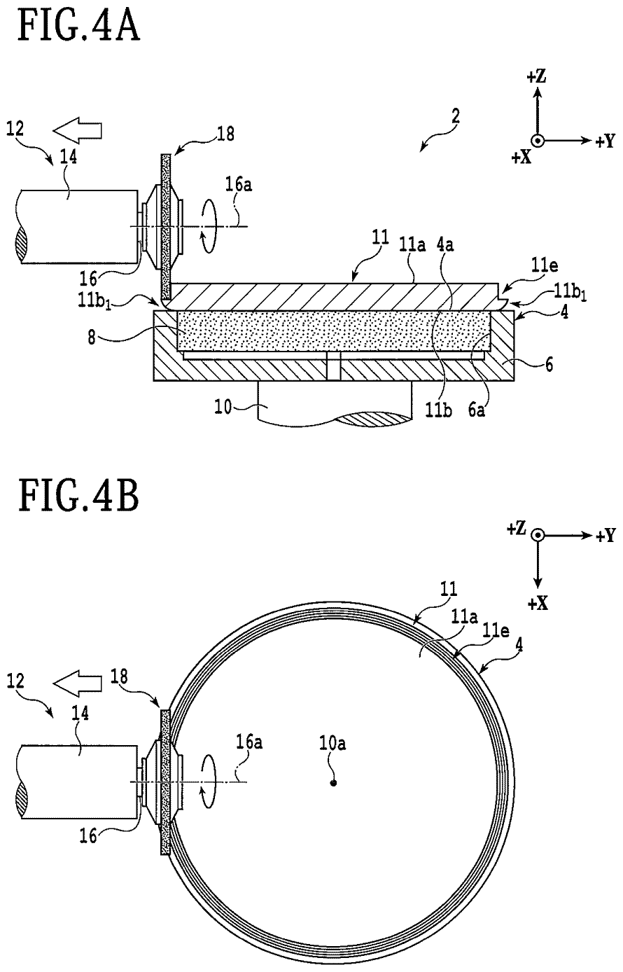

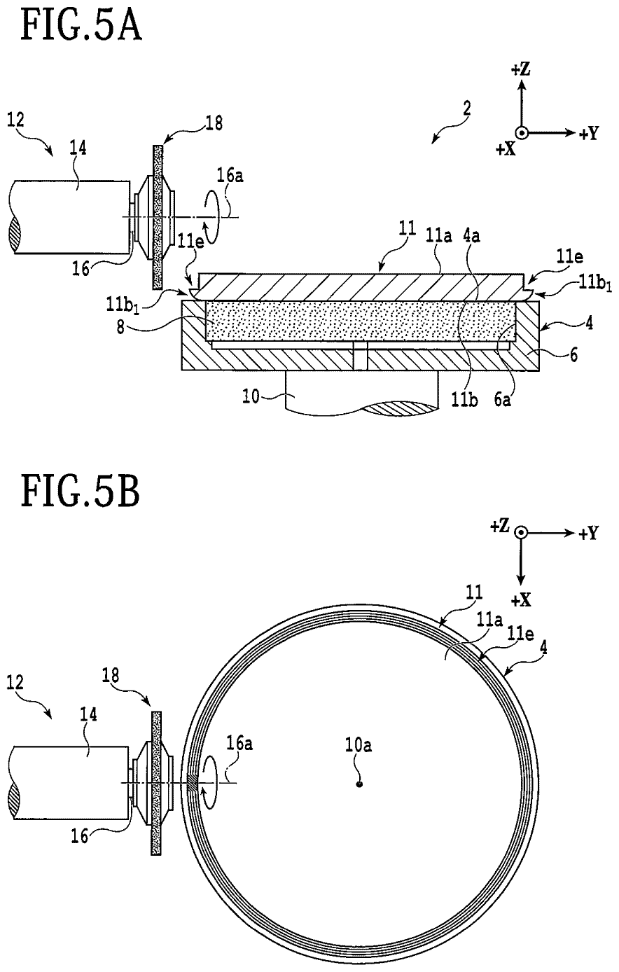

In the present embodiment, by using a cutting apparatus 2 (see FIGS. 3A and 3B), the chamfered portion 11a₁ of the front surface 11a is removed and an annular step portion 11e (see FIGS. 4A to 5B) is formed at an outer circumferential portion of the wafer 11.

Next, the cutting apparatus 2 is simply described with reference to FIG. 3A. An X-axis, a Y-axis, and a Z-axis depicted in FIG. 3A are orthogonal to each other. The X-axis is substantially parallel to a processing feed direction of the cutting apparatus 2. The Y-axis is substantially parallel to an indexing feed direction of the cutting apparatus 2. Further, the Z-axis is substantially parallel to the vertical direction.

In FIG. 3A, a +X-direction, a +Y-direction, and a +Z-direction are depicted. Note that the X-axis direction includes the +X-direction and a −X-direction that are parallel to the X-axis and are opposite directions to each other. Similarly, the Y-axis direction includes the +Y-direction and a −Y-direction that are parallel to the Y-axis and are opposite directions to each other, and the Z-axis direction includes the +Z-direction and a −Z-direction that are parallel to the Z-axis and are opposite directions to each other.

As depicted in FIG. 3A, the cutting apparatus 2 has a chuck table 4 with a circular disc shape. The chuck table 4 has a frame body 6 that is formed of a non-porous hard resin and has a circular disc shape. A recess portion 6a with a circular disc shape is made at a central portion of the upper surface of the frame body 6. A porous plate 8 that is formed of a porous ceramic and has a circular disc shape is fixed to the recess portion 6a by using an adhesive or the like.

The annular upper surface of the frame body 6 and the upper surface of the porous plate 8 form a holding surface 4a that sucks and holds the wafer 11. The holding surface 4a is substantially flush, and is disposed substantially in parallel to an X-Y-plane. A flow path for transmitting a negative pressure to the porous plate 8 is formed in the frame body 6.

A vacuum generating apparatus (not depicted) such as a vacuum pump is connected to the flow path of the frame body 6. The wafer 11 is sucked and held by a negative pressure transmitted from the vacuum generating apparatus to the holding surface 4a. The chuck table 4 is not limited to this example.

The chuck table 4 may have the above-described frame body 6 having substantially the same outer diameter as that of the wafer 11 without having the porous plate 8. In this case, an annular suction groove for supplying a negative pressure is made in the annular upper surface of the frame body 6, and the wafer 11 is sucked and held by the negative pressure transmitted to the annular suction groove.

A rotating shaft 10 is coupled to a bottom portion of the chuck table 4. The longitudinal direction of the rotating shaft 10 is substantially parallel to the Z-axis. When power is transmitted from a rotational drive source (not depicted) such as a motor to the rotating shaft 10, the chuck table 4 rotates around the rotating shaft 10.

By adjusting operation of the motor, the direction of the rotation of the chuck table 4 can be set to either a clockwise direction or a counterclockwise direction in top view, and a rotation speed of the chuck table 4 can be set to any value.

The chuck table 4 and the rotational drive source are supported by an X-axis direction movement mechanism (not depicted) having a ball screw, a servomotor, and the like, and is configured to be movable along the X-axis. The X-axis direction movement mechanism is referred to also as processing feed mechanism.

A cutting unit 12 is disposed on the upper side relative to the holding surface 4a of the chuck table 4. The cutting unit 12 has a spindle housing 14 with a longitudinal portion disposed along the Y-axis direction. In the spindle housing 14, part of a circular columnar spindle 16 is rotatably housed by air bearings (that is, aerostatic bearings).

The longitudinal direction of the spindle 16 is disposed substantially in parallel to the Y-axis. That is, the longitudinal direction of the spindle 16 is disposed along the holding surface 4a. A stator (not depicted) is disposed in the spindle housing 14, and a rotor that forms a motor with the stator is disposed at part of the spindle 16.

A tip portion of the spindle 16 protrudes to the outside of the spindle housing 14. A cutting blade 18 having an annular cutting edge is mounted on the tip portion of the spindle 16 by using a blade mount, a fixing nut, and the like.

The cutting blade 18 has abrasive grains formed of diamond or the like and a bond material for binding the abrasive grains. The cutting blade 18 rotates around the spindle 16 by rotation of the spindle 16.

A Z-axis direction movement mechanism (not depicted) having a ball screw, a servomotor, and the like is attached to the spindle housing 14. The cutting unit 12 can move along the Z-axis by the Z-axis direction movement mechanism. This allows adjustment of the depth of cutting of the cutting blade 18 into the wafer 11. The Z-axis direction movement mechanism is referred to also as cutting-in feed mechanism.

The Z-axis direction movement mechanism is configured to be allowed to move along the Y-axis by a Y-axis direction movement mechanism (not depicted) having a ball screw, a servomotor, and the like. The cutting unit 12 can move along the Y-axis by the Y-axis direction movement mechanism. That is, the cutting blade 18 can be moved along the Y-axis. The Y-axis direction movement mechanism is referred to also as indexing feed mechanism.

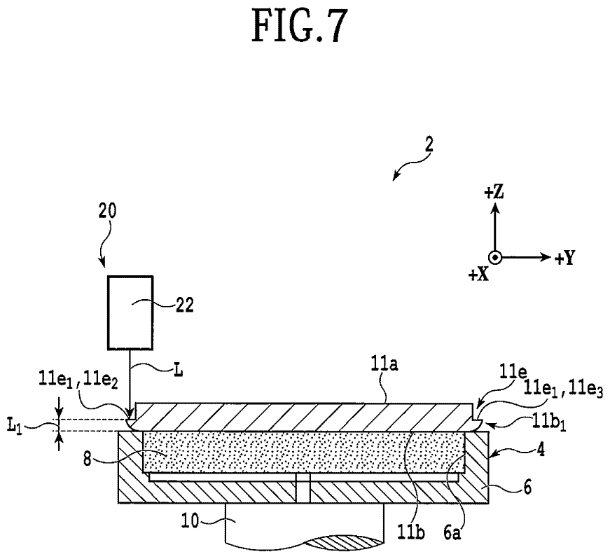

In the present embodiment, a sensor head 22 (see FIG. 7) of a thickness measuring instrument 20 that measures the thickness of the outer circumferential portion of the wafer 11 in a contactless manner by an optical method is fixed on one side of the spindle housing 14 in the X-axis direction.

Therefore, the sensor head 22 can move along the Y-axis and the Z-axis together with the spindle housing 14. However, the sensor head 22 may be movable along the X-axis, the Y-axis, and the Z-axis independently of the spindle housing 14.

The thickness measuring instrument 20 of the present embodiment is a thickness measuring instrument of a spectral interferometry system, and includes a super luminescent diode (SLD) light source (not depicted) that emits light in such a near-infrared wavelength band as to be allowed to be transmitted through the wafer 11, the sensor head 22, a spectrometer (not depicted), a waveform analysis section (not depicted) implemented through execution of a program by a processor, and the like.

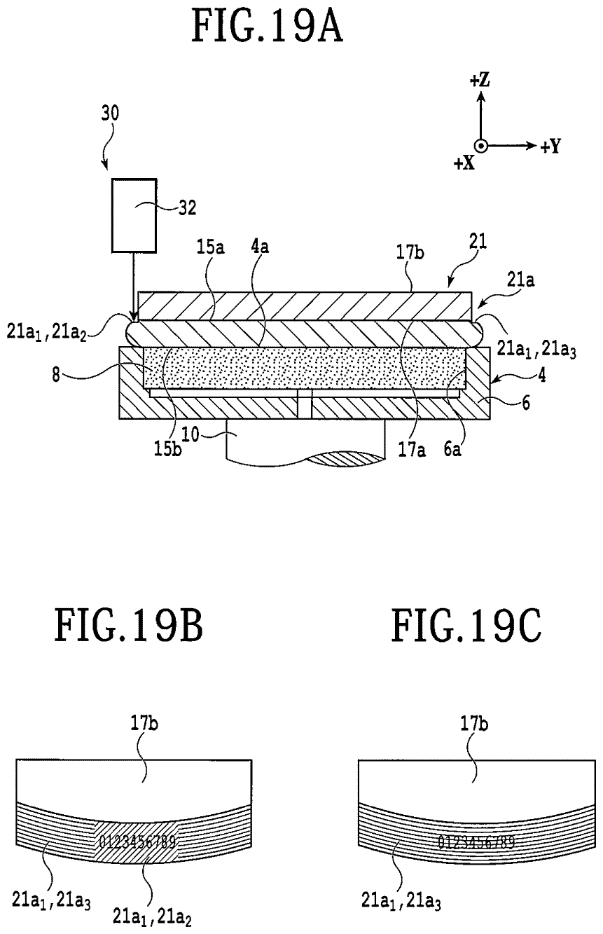

In the present embodiment, a microscope camera 30 (see FIG. 19A) that images the wafer 11 by using visible light is fixed on the other side of the spindle housing 14 in the X-axis direction. The microscope camera 30 can also move along the Y-axis and the Z-axis together with the spindle housing 14.

However, the microscope camera 30 may be movable along the X-axis, the Y-axis, and the Z-axis independently of the spindle housing 14. Next, each step depicted in FIG. 1 is described with reference to FIGS. 3A to 7.

FIG. 3A is a partially sectional side view depicting the first cutting step S10. FIG. 3B is a top view depicting the first cutting step S10. In the first cutting step S10, first, the wafer 11 is sucked and held by the holding surface 4a of the chuck table 4.

Subsequently, a lower end of the cutting blade 18 that rotates at high speed, with the spindle 16 being a rotating shaft, is positioned to a height between the front surface 11a and the back surface 11b. For example, a rotation speed of the spindle 16 is set to 30,000 rpm, and the height of the lower end of the cutting blade 18 is set to a predetermined value of at least several tens of micrometers and at most 100 μm from the front surface 11a.

Then, the chuck table 4 is moved along the X-axis direction relative to the cutting unit 12. Specifically, the chuck table 4 is moved along the X-axis to such a position that, in top view, an extended line of a rotation center 16a of the spindle 16 in the Y-axis direction intersects a rotation center 10a of the rotating shaft 10. Thereby, the cutting blade 18 is made to cut into the chamfered portion 11a₁ of the wafer 11.

When the cutting unit 12 is movable along the X-axis, the cutting of the cutting blade 18 into the chamfered portion 11a₁ may be implemented by moving the cutting unit 12 along the X-axis.

Further, the movement for the cutting-in is not limited to the movement of the chuck table 4 or the cutting unit 12 in the X-axis direction. The cutting-in may be implemented by relatively moving the chuck table 4 and the cutting unit 12 along the Z-axis (that is, lowering the cutting unit 12 along the Z-axis or raising the chuck table 4 along the Z-axis).

In any case, by making the cutting blade 18 cut into the chamfered portion 11a₁ of the front surface 11a and rotating the chuck table 4 at a predetermined rotation speed (for example, 5°/s) by one or more revolutions around the rotating shaft 10, the outer circumferential portion of the front surface 11a of the wafer 11 is cut to form the step portion 11e (see FIGS. 4A and 4B).

The step portion 11e is defined by an outer circumferential side surface that is substantially orthogonal to the front surface 11a and has a circular cylindrical shape and an annular bottom portion (that is, bottom portion 11e₁ to be described later) that connects to the outer circumferential side surface at an end portion located on the opposite side to the front surface 11a in the thickness direction 11c in this outer circumferential side surface.

When the blade thickness of the cutting blade 18 is sufficiently large compared with the width of the step portion 11e, for example, the step portion 11e can be formed by causing the chuck table 4 to make one revolution.

In contrast, when the blade thickness of the cutting blade 18 is smaller than the width of the step portion 11e, while the rotation of the chuck table 4 is continued, cutting of the cutting blade 18 into the wafer 11 in the X-axis direction, drawing of the cutting blade 18 from the wafer 11 in the X-axis direction, and position adjustment of the cutting blade 18 relative to the wafer 11 in the Y-axis direction are repeated.

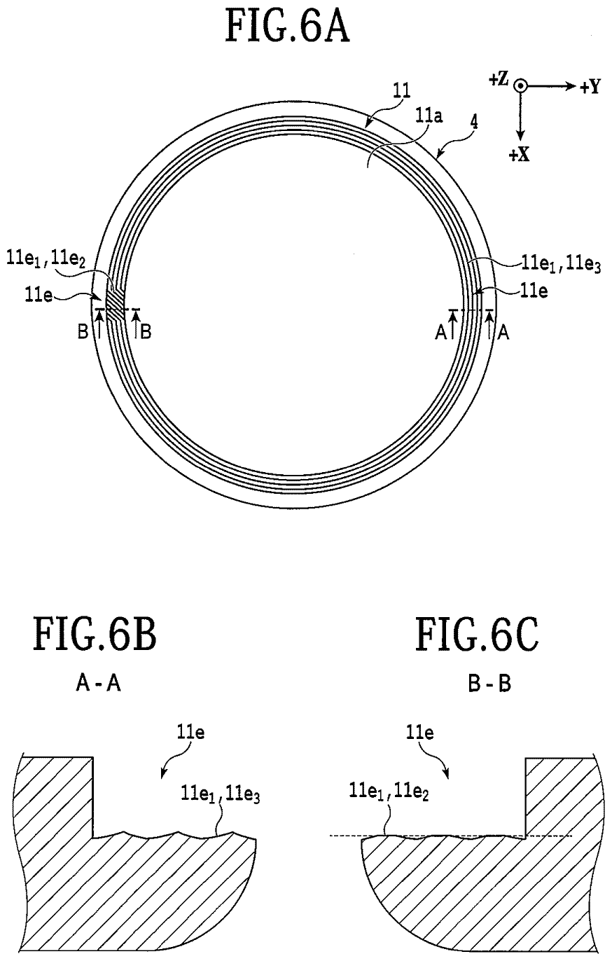

In the first cutting step S10, a cutting mark with a shape of concentric circles is formed in the bottom portion 11e₁ of the step portion 11e (see FIGS. 6B and 6C) due to the rotation of the chuck table 4. The cutting mark with the shape of concentric circles forms roughness in the bottom portion 11e₁ (see FIG. 6B).

The roughness in the bottom portion 11e₁ is formed, for example, due to variation in the protrusion amount (that is, protrusion length) of the abrasive grain protruding from the bond material in the cutting blade 18 in the blade thickness direction of the cutting blade 18.

In the present embodiment, after the first cutting step S10, the bottom portion 11e₁ of the step portion 11e is cut by relatively moving the chuck table 4 and the cutting unit 12 (that is, spindle 16) (second cutting step S20).

FIG. 4A is a partially sectional side view depicting the time of start of the second cutting step S20. FIG. 4B is a top view depicting the time of the start of the second cutting step S20.

The second cutting step S20 includes relatively moving the chuck table 4 and the cutting blade 18 along the Y-axis in a state in which the height position of the cutting unit 12 (that is, spindle 16) relative to the chuck table 4 is kept.

In the second cutting step S20 of the present embodiment, in a state in which the rotation of the spindle 16 is kept and the chuck table 4 is made still in the cutting apparatus 2 without being rotated, the cutting unit 12 (that is, the spindle 16, the cutting blade 18, and the like) is moved along the Y-axis outward in a radial direction of the holding surface 4a (that is, in the −Y-direction) at a predetermined speed of at least 1 mm/s and at most 50 mm/s.

In the second cutting step S20, similarly to spark-out in grinding processing for the wafer 11 using a grinding wheel, the amount of cutting-in feed of the cutting blade 18 in the Z-axis direction is set to zero (that is, in a state in which the height position of the cutting blade 18 is kept), the cutting blade 18 that is rotating around the spindle 16 is moved along the Y-axis outward in the radial direction of the holding surface 4a.

In this manner, the chuck table 4 and the cutting blade 18 are relatively moved along the Y-axis until the lower end of the cutting blade 18 completely separates from the wafer 11. The movement direction of the cutting blade 18 relative to the chuck table 4 is not limited to the Y-axis direction.

The cutting blade 18 may be moved along the X-axis direction relative to the chuck table 4 until the lower end of the cutting blade 18 completely separates from the wafer 11. Moreover, relative to the chuck table 4, the cutting blade 18 may be moved along the Y-axis direction while being moved along the X-axis direction.

In short, it is sufficient that the bottom portion 11e₁ of the step portion 11e can be cut by moving the cutting blade 18 in parallel along the holding surface 4a in the X-Y-plane in the state in which the height position of the cutting blade 18 that is rotating is kept.

FIG. 5A is a partially sectional side view depicting the time of end of the second cutting step S20. FIG. 5B is a top view depicting the time of the end of the second cutting step S20. Further, FIG. 6A is a top view of the wafer 11 after the second cutting step S20.

FIG. 6B is a schematic sectional view along line A-A in FIG. 6A concerning a portion for which cutting has not been executed in the second cutting step S20. FIG. 6C is a schematic sectional view along line B-B in FIG. 6A concerning a portion for which cutting has been executed in the second cutting step S20.

FIGS. 6B and 6C are diagrams depicting, as an example, a form of the bottom portion 11e₁ of the step portion 11e conceivable at this time, and the shape of the bottom portion 11e₁ of the step portion 11e is not limited to FIGS. 6B and 6C.

In a roughness-reduced region 11e₂ resulting from execution of the second cutting step S20, a cutting mark having a pattern in an oblique direction in top view is newly formed (see FIGS. 5B and 6A) in association with moving the cutting blade 18 relative to the wafer 11 while rotating the cutting blade 18.

However, in the roughness-reduced region 11e₂, the roughness is reduced compared with a roughness-non-reduced region 11e₃ in which the second cutting step S20 has not been executed in the bottom portion 11e₁ (see FIG. 6C). That is, in the second cutting step S20, the roughness formed in the bottom portion 11e₁ of the step portion 11e in the first cutting step S10 can be reduced.

After the second cutting step S20, the measurement step S30 is executed. FIG. 7 is a partially sectional side view depicting the measurement step S30. In the measurement step S30, the bottom portion 11e₁ of the step portion 11e for which the second cutting step S20 has been executed (that is, roughness-reduced region 11e₂) is irradiated with measurement light L from the sensor head 22, and a distance L₁ from the back surface 11b of the wafer 11 to the bottom portion 11e₁ of the step portion 11e is measured.

By measuring a distance L₂ (not depicted) from the sensor head 22 to the holding surface 4a in advance, when a distance L₃ (not depicted) from the sensor head 22 to the bottom portion 11e₁ of the step portion 11e is measured, the above-described distance L₁ (see FIG. 7), which is a difference between the distance L₂ and the distance L₃, is obtained. The distance L₁ is the remaining thickness of the wafer 11 formed at the outer circumferential portion of the wafer 11 due to the formation of the step portion 11e.

In the present embodiment, as a result of the reduction in the roughness of the bottom portion 11e₁ of the step portion 11e, the measurement light L with which the roughness-reduced region 11e₂ is irradiated becomes more liable to be properly reflected by the bottom portion 11e₁ of the step portion 11e. Thus, the remaining thickness of the wafer 11 at the outer circumferential portion can be accurately measured compared with a case of irradiating the roughness-non-reduced region 11e₃ with the measurement light L.

### Second Embodiment

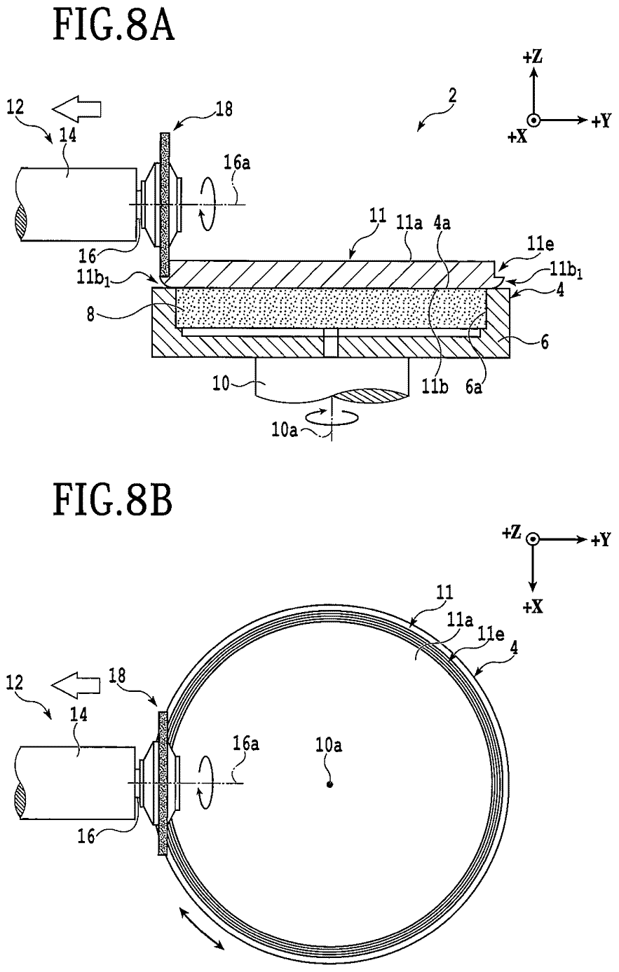

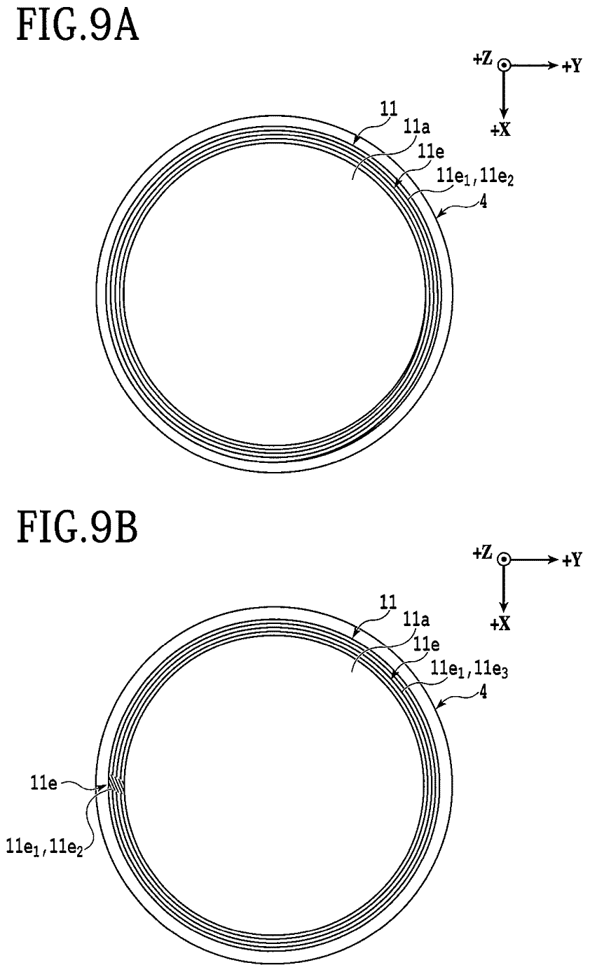

Next, a second embodiment is described with reference to FIGS. 8A to 9B. FIG. 8A is a partially sectional side view depicting the time of start of the second cutting step S20 according to the second embodiment. FIG. 8B is a top view depicting the time of the start of the second cutting step S20 according to the second embodiment.

In the second cutting step S20 of the second embodiment, while rotation of the spindle 16 is kept and the chuck table 4 is rotated in a clockwise manner or a counterclockwise manner, the cutting blade 18 is moved along the Y-axis outward in the radial direction of the holding surface 4a. This point is different from the first embodiment.

FIG. 9A is a top view depicting a first example of the wafer 11 after the second cutting step S20 according to the second embodiment. FIG. 9A depicts an example in which a spiral cutting mark is formed in the step portion 11e because a speed of the rotation of the chuck table 4 is high compared with the speed of the movement of the cutting blade 18 in the Y-axis direction.

Also, in the first example, the roughness formed in the bottom portion 11e₁ of the step portion 11e can be reduced. Moreover, in FIG. 9A, the roughness-reduced region 11e₂ exists in substantially the whole of the bottom portion 11e₁ of the step portion 11e. Thus, there is an advantage that thickness measurement using the measurement light L is possible at any position on the bottom portion 11e₁.

FIG. 9B is a top view depicting a second example of the wafer 11 after the second cutting step S20 according to the second embodiment. In FIG. 9B, the chuck table 4 is rotated in a counterclockwise manner.

FIG. 9B depicts an example in which the roughness-reduced region 11e₂ becomes not the rectangle depicted in FIG. 6A but a substantially parallelogram because the speed of the movement of the cutting blade 18 in the Y-axis direction is high compared with the speed of the rotation of the chuck table 4.

Also, in the second example, the roughness formed in the bottom portion 11e₁ of the step portion 11e can be reduced. Further, although the range of the roughness-reduced region 11e₂ in FIG. 9B is small compared with the range of the roughness-reduced region 11e₂ in FIG. 9A, there is an advantage that the second cutting step S20 can be completed in a short time compared with the second cutting step S20 of FIG. 9A.

### Third Embodiment

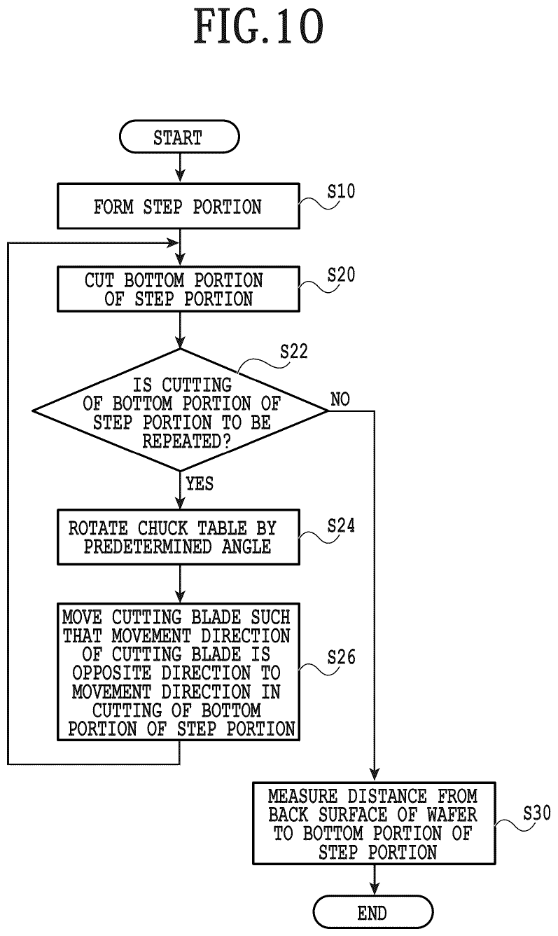

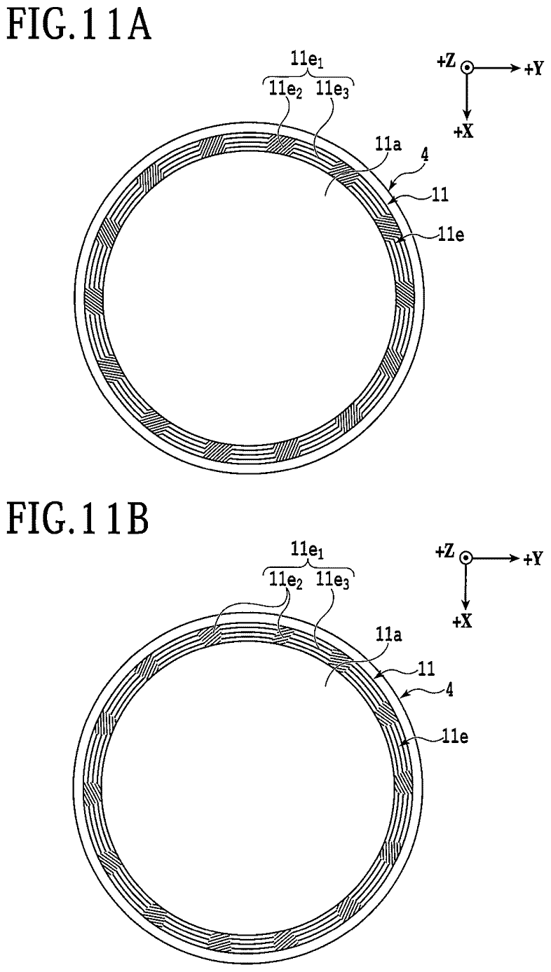

Next, a third embodiment is described with reference to FIGS. 10 to 11B. FIG. 10 is a flowchart of a cutting method for the wafer 11 in the third embodiment. In the third embodiment, in a case in which the second cutting step S20 is not repeated after the second cutting step S20 (NO in determination step S22), the flow is ended after the above-described measurement step S30 is executed.

In contrast, in a case in which the second cutting step S20 is repeated after the second cutting step S20 (YES in determination step S22), the process is advanced to a chuck table rotation step S24 of rotating the chuck table 4 by a predetermined angle. The rotation angle is not particularly limited, and falls within a range of, for example, 5° to 180°. After the chuck table rotation step S24, the process is advanced to a third cutting step S26.

In the third cutting step S26, in a state in which the height position of the spindle 16 relative to the chuck table 4 is kept, the cutting blade 18 is moved relative to the chuck table 4 in the opposite direction (for example, +Y-direction) to the movement direction of the cutting blade 18 relative to the chuck table 4 in the second cutting step S20 (for example, −Y-direction).

Also, in the third cutting step S26, the roughness formed in the bottom portion 11e₁ of the step portion 11e can be reduced similarly to the second cutting step S20. At the time of end of the third cutting step S26, the relative position of the cutting blade 18 in the radial direction of the chuck table 4 is the same as that of the cutting blade 18 in the radial direction of the chuck table 4 at the time of end of the first cutting step S10.

Then, after the third cutting step S26, the process returns to the second cutting step S20. After the second cutting step S20, when YES is made in the determination step S22 again, the process is advanced to the third cutting step S26 through the chuck table rotation step S24. In this manner, in the present embodiment, the second cutting step S20, the chuck table rotation step S24 after the second cutting step S20, and the third cutting step S26 after the chuck table rotation step S24 are repeated in that order a plurality of times.

FIG. 11A is a top view depicting a first example of the wafer 11 cut by the cutting method of the third embodiment. In the first example, the roughness-reduced region 11e₂ is formed in the bottom portion 11e₁ of the step portion 11e in each of the second cutting step S20 and the third cutting step S26.

Therefore, a plurality of roughness-reduced regions 11e₂ are formed at substantially equal intervals along the circumferential direction of the wafer 11 by repeating the second cutting step S20, the chuck table rotation step S24, and the third cutting step S26.

FIG. 11B is a top view depicting a second example of the wafer 11 cut by the cutting method of the third embodiment. In the second example, similarly to FIG. 9B of the second embodiment, the chuck table 4 is rotated in a predetermined direction in each of the second cutting step S20 and the third cutting step S26.

In the second cutting step S20, the cutting blade 18 is moved from the inside toward the outside in the radial direction of the holding surface 4a. In the third cutting step S26, the cutting blade 18 is moved from the outside toward the inside in the radial direction of the holding surface 4a. Thus, the shape of the roughness-reduced region 11e₂ differs between the second cutting step S20 and the third cutting step S26.

### Fourth Embodiment

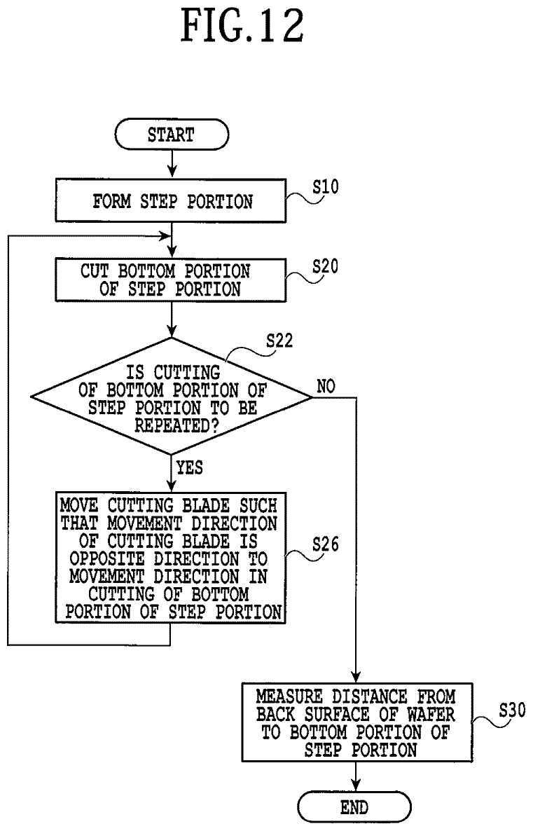

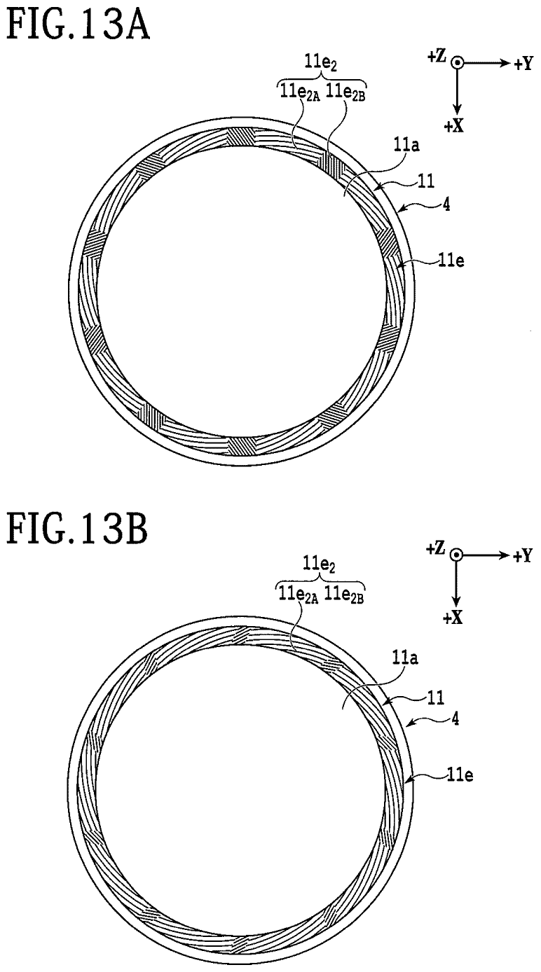

Next, a fourth embodiment is described with reference to FIGS. 12 to 13B. FIG. 12 is a flowchart of a cutting method for the wafer 11 in the fourth embodiment. FIG. 13A is a top view depicting a first example of the wafer 11 cut by the cutting method of the fourth embodiment.

In the first example of the fourth embodiment, in a case in which the second cutting step S20 is repeated after the second cutting step S20 (YES in determination step S22), the process is advanced to the third cutting step S26 without going through the chuck table rotation step S24 in the third embodiment.

Note that, in the second cutting step S20, the chuck table 4 and the cutting blade 18 are relatively moved while the chuck table 4 is rotated (that is, in a state in which the rotation is continued). Thereby, the cutting blade 18 is made farther away from the step portion 11e.

In this second cutting step S20, a spiral roughness-reduced region 11e_{2A} depicted in FIG. 13A is formed in the bottom portion 11e₁. When the cutting blade 18 has been completely separated from the wafer 11 (that is, when the second cutting step S20 has ended), the rotation of the chuck table 4 is stopped.

Then, the third cutting step S26 is executed in a state in which the rotation of the chuck table 4 is stopped. In the third cutting step S26, a substantially rectangular roughness-reduced region 11e_{2B} depicted in FIG. 13A is formed in the bottom portion 11e₁.

By repeating the second cutting step S20 and the third cutting step S26 a plurality of times, the roughness-reduced regions 11e_{2A} and the roughness-reduced regions 11e_{2B} are periodically formed in the bottom portion 11e₁. In each cutting step, the rotation of the cutting blade 18 (that is, spindle 16) is continued naturally.

FIG. 13B is a top view depicting a second example of the wafer 11 cut by the cutting method of the fourth embodiment. In the second example of the fourth embodiment, the second cutting step S20 and the third cutting step S26 are repeated while the chuck table 4 is rotated (that is, in a state in which the rotation is continued).

However, the speed of the movement of the cutting blade 18 relative to the speed of the rotation of the chuck table 4 in the second cutting step S20 is comparatively low, and the speed of the movement of the cutting blade 18 relative to the speed of the rotation of the chuck table 4 in the third cutting step S26 is comparatively high.

Therefore, in the second cutting step S20, the spiral roughness-reduced region 11e_{2A} is formed in the bottom portion 11e₁. In the third cutting step S26, the roughness-reduced region 11e_{2B} with a substantially parallelogram shape similar to that in FIG. 9B of the second embodiment is formed in the bottom portion 11e₁.

### Fifth Embodiment

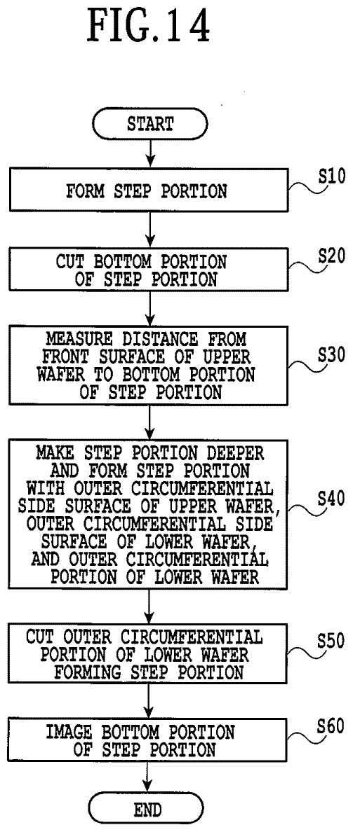

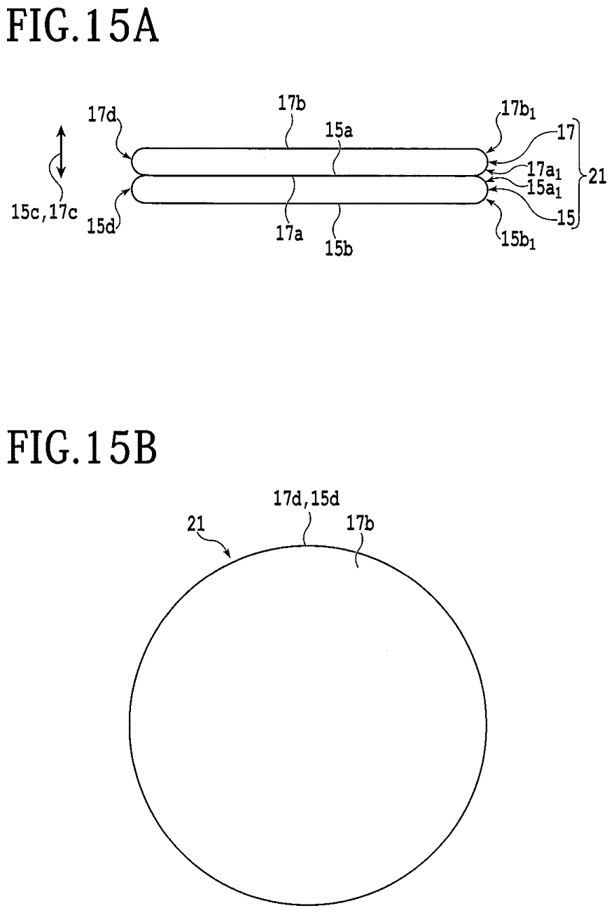

Next, a fifth embodiment is described with reference to FIGS. 14 to 19C. FIG. 14 is a flowchart of a cutting method for a bonded wafer 21 (see FIGS. 15A and 15B) in the fifth embodiment.

First, the bonded wafer (that is, workpiece) 21 is described. FIG. 15A is a side view of the bonded wafer 21. FIG. 15B is a top view of the bonded wafer 21.

The bonded wafer 21 has a lower wafer 15 and an upper wafer 17 fixed to each other, with a joining layer (not depicted) interposed therebetween, and is referred to also as stacked wafer. The shape of each of the lower wafer 15 and the upper wafer 17 is substantially the same as the above-described wafer 11.

The lower wafer 15 has a front surface (that is, the other surface) 15a and a back surface (that is, one surface) 15b. The front surface 15a and the back surface 15b are located on the opposite sides in a thickness direction 15c of the lower wafer 15.

A plurality of planned dividing lines (not depicted) are set in a lattice manner in the front surface 15a of the lower wafer 15. A device (not depicted) such as an IC is formed in each of rectangular regions marked out by the plurality of planned dividing lines.

The devices are not necessarily required to be made in the lower wafer 15. The lower wafer 15 may be a substrate that has substantially the same diameter as the upper wafer 17 without having the device and is formed of a semiconductor, resin, metal, ceramic, glass, or the like.

The front surface 15a of the lower wafer 15 has a chamfered portion 15a₁ at an outer circumferential portion. Similarly, the back surface 15b also has a chamfered portion 15b₁ at an outer circumferential portion. In the thickness direction 15c, an edge 15d that defines the outermost circumference of the lower wafer 15 exists between the chamfered portion 15a₁ of the front surface 15a and the chamfered portion 15b₁ of the back surface 15b.

The shape of the lower wafer 15 is not limited to the shape depicted in FIG. 15A. The lower wafer 15 is not required to have the chamfered portion 15a₁ at the outer circumferential portion of the front surface 15a and the chamfered portion 15b₁ at the outer circumferential portion of the back surface 15b, and an intersection region between the outer circumferential side surface of the lower wafer 15 and the front surface 15a may be angular, in addition, another intersection region between the outer circumferential side surface of the lower wafer 15 and the back surface 15b may be angular.

The upper wafer 17 also has a front surface 17a and a back surface 17b located on the opposite sides in a thickness direction 17c. The front surface 17a of the upper wafer 17 is segmented by a plurality of planned dividing lines. A device (not depicted) is formed in each of rectangular regions marked out by the plurality of planned dividing lines.

The front surface 17a of the upper wafer 17 has a chamfered portion 17a₁ at an outer circumferential portion. Similarly, the back surface 17b also has a chamfered portion 17b₁ at an outer circumferential portion. In the thickness direction 17c, an edge 17d that defines the outermost circumference of the upper wafer 17 exists between the chamfered portion 17a₁ of the front surface 17a and the chamfered portion 17b₁ of the back surface 17b.

In the present embodiment, steps from the first cutting step S10 to an imaging step S60 depicted in FIG. 14 are executed by using the above-described cutting apparatus 2. The first cutting step S10 of the present embodiment is substantially the same as the first cutting step S10 in the first embodiment, and thus overlapping description is omitted in some cases.

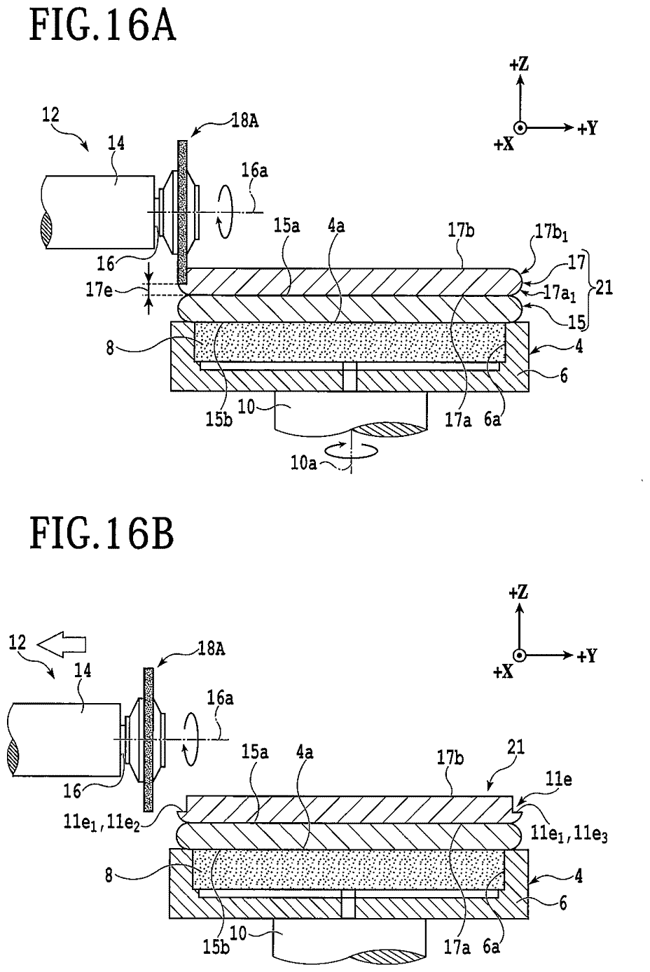

FIG. 16A is a partially sectional side view depicting the first cutting step S10. In the first cutting step S10 of the present embodiment, a cutting blade (generally-called rough blade) 18A in which the average grain diameter of abrasive grains is comparatively large is used.

In the first cutting step S10, the cutting blade 18A is made to cut into the outer circumferential portion of the upper wafer 17 such that the thickness from the bottom portion 11e₁ of the step portion 11e to the front surface 17a (that is, remaining thickness 17e of the step portion 11e) in the thickness direction 15c or 17c becomes a predetermined value of at least 10 μm and at most 50 μm.

By rotating the chuck table 4 after making the cutting blade 18A cut into the outer circumferential portion of the upper wafer 17 in this manner, the step portion 11e is formed at the outer circumferential portion on the side of the back surface 17b of the upper wafer 17 similarly to the first embodiment. After the first cutting step S10, the second cutting step S20 is executed similarly to the first embodiment.

FIG. 16B is a partially sectional side view depicting the second cutting step S20. The second cutting step S20 of the present embodiment is substantially the same as the second cutting step S20 in the first embodiment, and thus overlapping description is omitted in some cases.

In the second cutting step S20, in a state in which the rotation of the spindle 16 is kept and the chuck table 4 is made still in the cutting apparatus 2 without being rotated, the cutting unit 12 is moved along the Y-axis outward in the radial direction of the holding surface 4a.

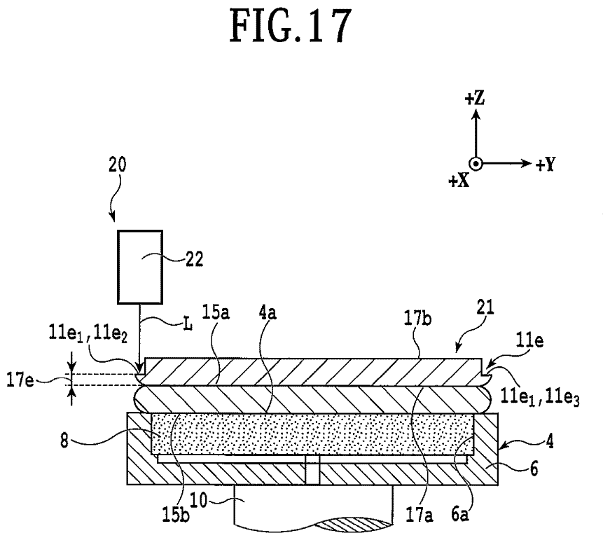

Thereby, the bottom portion 11e₁ of the step portion 11e of the upper wafer 17 is cut, and the roughness-reduced region 11e₂ is formed in the bottom portion 11e₁. After the second cutting step S20, the measurement step S30 is executed. FIG. 17 is a partially sectional side view depicting the measurement step S30.

In the measurement step S30, the roughness-reduced region 11e₂ formed by the second cutting step S20 is irradiated with the measurement light L. Thus, the remaining thickness 17e at the outer circumferential portion of the upper wafer 17 can be accurately measured compared with a case of irradiating the roughness-non-reduced region 11e₃ with the measurement light L. Therefore, the cutting-in depth position of a cutting blade 18B in a subsequent additional first cutting step S40 can be controlled with high accuracy.

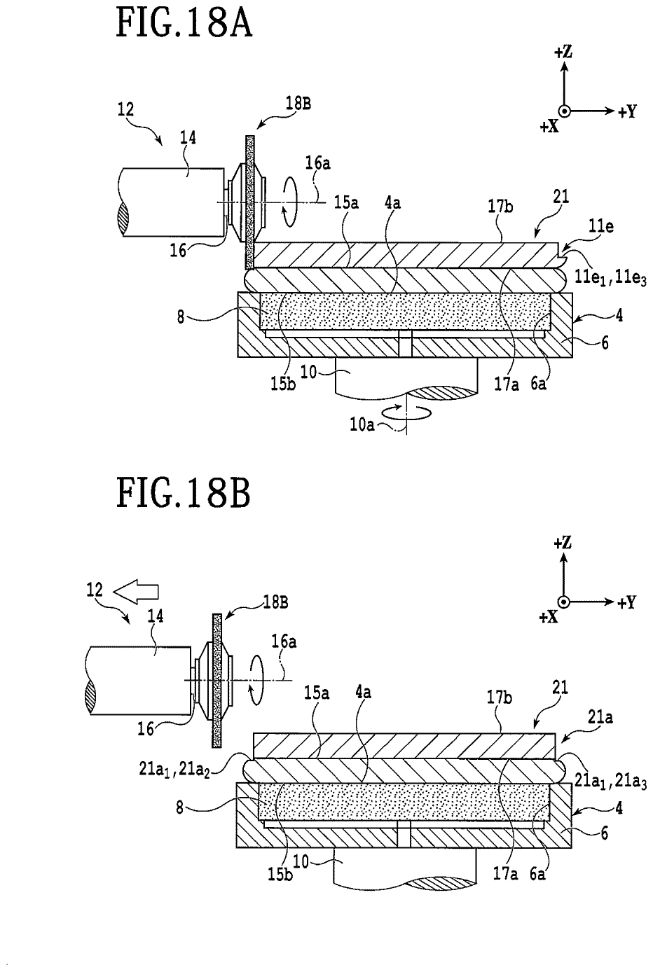

After the measurement step S30, the additional first cutting step S40 is executed. FIG. 18A is a partially sectional side view depicting the additional first cutting step S40. In the additional first cutting step S40, a cutting blade (generally-called finishing blade) 18B in which the average grain diameter of abrasive grains is small compared with the average grain diameter of the abrasive grains of the cutting blade 18A is used.

In the additional first cutting step S40, similarly to the first cutting step S10, the cutting blade 18B is made to cut into the bottom portion 11e₁ of the step portion 11e of the upper wafer 17, and the chuck table 4 is rotated. Specifically, the lower end of the cutting blade 18B is set to a position deeper than the front surface 15a of the lower wafer 15 by approximately 1 μm to 2 μm, and the chuck table 4 is rotated.

This makes the step portion 11e deeper, and forms a step portion 21a composed of the circular cylindrical outer circumferential side surface of the upper wafer 17, the circular cylindrical outer circumferential side surface located near the front surface 15a in the lower wafer 15, and an annular outer circumferential portion (that is, bottom portion 21a₁ to be described later) that is not covered by the upper wafer 17 and is exposed.

After the additional first cutting step S40, an additional second cutting step S50 is executed. FIG. 18B is a partially sectional side view depicting the additional second cutting step S50. The cutting blade 18B is used also in the additional second cutting step S50.

Also, in the additional second cutting step S50, similarly to the second cutting step S20, the outer circumferential portion of the lower wafer 15 forming the step portion 21a is cut by relatively moving the chuck table 4 and the cutting blade 18. Thereby, a roughness-reduced region 21a₂ is formed in the bottom portion 21a₁ of the step portion 21a. The bottom portion 21a₁ other than the roughness-reduced region 21a₂ is a roughness-non-reduced region 21a₃.

After the additional second cutting step S50, the imaging step S60 is executed. FIG. 19A is a partially sectional side view depicting the imaging step S60. In the imaging step S60, for example, the microscope camera 30 that images a subject by a visible light beam is used.

The microscope camera 30 has a light source, an objective lens, an image forming lens, a solid-state imaging element (none is depicted), and the like. In the imaging step S60, a lens unit 32 provided with the objective lens is disposed above the step portion 21a, and the bottom portion 21a₁ of the step portion 21a for which the additional second cutting step S50 has been executed (that is, roughness-reduced region 21a₂) is imaged.

An identification (ID) number is made in the outer circumferential portion of the front surface 15a of the lower wafer 15. The ID number is formed to a certain depth from the front surface 15a by laser marking or the like. Thus, the ID number remains in the outer circumferential portion of the front surface 15a also after the additional second cutting step S50.

In the imaging step S60, the roughness-reduced region 21a₂ formed by the additional second cutting step S50 is imaged. Thus, there is an advantage that the ID number remaining in the outer circumferential portion of the lower wafer 15 can be imaged more clearly.

FIG. 19B is a schematic diagram of an image obtained in the imaging step S60 of the fifth embodiment. In contrast, FIG. 19C is a schematic diagram of an image obtained in an existing imaging step of imaging the outer circumferential portion of the lower wafer 15 for which the additional second cutting step S50 has not been executed.

Although detailed description is omitted, also in the fifth embodiment, the second embodiment may be applied in the second cutting step S20, and the third embodiment or the fourth embodiment in which the third cutting step S26 is executed may be applied in the process from the second cutting step S20 to the measurement step S30.

Also, in the additional second cutting step S50, the second embodiment may be applied similarly. Also, in the process from the additional second cutting step S50 to the imaging step S60, the third embodiment or the fourth embodiment in which the third cutting step S26 is executed may be applied similarly.

Besides, structures, methods, and the like according to the above-described embodiments can be carried out with appropriate changes without departing from the scope of the object of the present invention. The bottom portions 11e₁ and 21a₁ of the step portions 11e and 21a may be read as bottom surface.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A cutting method for a workpiece by which a chamfered portion in one surface of the workpiece having the chamfered portion at an outer circumferential portion of the one surface is removed and an annular step portion is formed at the outer circumferential portion of the one surface, the cutting method comprising:
cutting the outer circumferential portion of the one surface of the workpiece to form the step portion by causing a cutting blade mounted on a tip portion of a spindle with a longitudinal direction disposed along a holding surface of a chuck table to cut into the chamfered portion of the one surface of the workpiece held by the holding surface and rotating the chuck table; and
cutting a bottom portion of the step portion by relatively moving the chuck table and the cutting blade after cutting the outer circumferential portion to form the step portion, wherein
the cutting the bottom portion of the step portion includes relatively moving the chuck table and the cutting blade along the longitudinal direction of the spindle in a state in which a height position of the spindle relative to the chuck table is kept.

2. The cutting method for a workpiece according to claim 1, wherein,
in the cutting the bottom portion of the step portion, the chuck table and the cutting blade are relatively moved while the chuck table is rotated.

3. The cutting method for a workpiece according to claim 2, further comprising:
moving the cutting blade relative to the chuck table such that a movement direction of the cutting blade relative to the chuck table is an opposite direction to a movement direction of the cutting blade relative to the chuck table in the cutting the bottom portion of the step portion in the state in which the height position of the spindle relative to the chuck table is kept, wherein the cutting the bottom portion of the step portion and the moving the cutting blade relative to the chuck table are repeated a plurality of times.

4. The cutting method for a workpiece according to claim 1, further comprising:
rotating the chuck table by a predetermined angle after the cutting the bottom portion of the step portion; and
after rotating the chuck table by the predetermined angle, moving the cutting blade relative to the chuck table such that a movement direction of the cutting blade relative to the chuck table is an opposite direction to a movement direction of the cutting blade relative to the chuck table in the cutting the bottom portion of the step portion in the state in which the height position of the spindle relative to the chuck table is kept.

5. The cutting method for a workpiece according to claim 4, wherein
the cutting the bottom portion of the step portion, the rotating the chuck table by the predetermined angle after the cutting the bottom portion of the step portion, and the moving the cutting blade relative to the chuck table after the rotating the chuck table by the predetermined angle are repeated in that order.

6. The cutting method for a workpiece according to claim 1, wherein
the workpiece has a lower wafer and an upper wafer that has chamfered portions at outer circumferential portions of both surfaces and is overlapped with and fixed to the lower wafer,
the step portion is formed at the outer circumferential portion of the upper wafer in the cutting the outer circumferential portion to form the step portion, and
a bottom portion of the step portion of the upper wafer is cut in the cutting the bottom portion of the step portion.

7. The cutting method for a workpiece according to claim 1, further comprising:
irradiating the bottom portion of the step portion for which the cutting the bottom portion of the step portion has been executed with measurement light from a sensor head and measuring a distance from another surface of the workpiece located on an opposite side to the one surface to the bottom portion of the step portion.

8. The cutting method for a workpiece according to claim 6, further comprising:
after the cutting the bottom portion of the step portion, making the step portion deeper and forming the step portion with an outer circumferential side surface of the upper wafer, an outer circumferential side surface of the lower wafer, and an outer circumferential portion of the lower wafer by causing the cutting blade to cut into the bottom portion of the step portion and rotating the chuck table; and
cutting the outer circumferential portion of the lower wafer forming the step portion after the making the step portion deeper.

9. The cutting method for a workpiece according to claim 8, further comprising:
imaging the bottom portion of the step portion for which the cutting the outer circumferential portion of the lower wafer has been executed.
